(19) United States
(12) Patent Application Publication
(10) Pub. No.: US 2026/0273924 A1
(43) Pub. Date: Sep. 17, 2026

(54) LIQUID DISCHARGE SYSTEM AND LIQUID DISCHARGE METHOD

(71) Applicants: Osamu MACHIDA, Kanagawa (JP); Tatsuhiro OHNO, Kanagawa (JP); Tohru HASEGAWA, Kanagawa (JP); Yukihiro WAKABAYASHI, Kanagawa (JP); Taihei NISHIMOTO, Kanagawa (JP); Yuko KOMAI, Kanagawa (JP)

(72) Inventors: Osamu MACHIDA, Kanagawa (JP); Tatsuhiro OHNO, Kanagawa (JP); Tohru HASEGAWA, Kanagawa (JP); Yukihiro WAKABAYASHI, Kanagawa (JP); Taihei NISHIMOTO, Kanagawa (JP); Yuko KOMAI, Kanagawa (JP)

(21) Appl. No.: 19/560,141

(22) Filed: Mar. 9, 2026

(30) Foreign Application Priority Data
Mar. 14, 2025 (JP) 2025-041671

(51) Int. Cl. B41J 2/045; B41J 2/14; B41J 2/17; B41J 2/175; H05K 3/12

(52) U.S. Cl. CPC B41J 2/04508; B41J 2/04581; B41J 2/14233; B41J 2/1433; B41J 2/1707; B41J 2/17566; B41J 2/17596; H05K 3/125; B41J 2202/16

(57) ABSTRACT

A liquid discharge system includes a liquid discharge head and a pressurizer. The liquid discharge head includes a nozzle member having a nozzle to discharge a liquid; a liquid chamber member having a liquid chamber communicating with the nozzle and storing the liquid to be supplied to the nozzle; and an actuator to deform the liquid chamber to discharge the liquid in the liquid chamber from the nozzle. The pressurizer applies pressure to the liquid in the liquid chamber to maintain the liquid in the liquid chamber at a positive pressure to perform a pressurizing operation. The liquid discharge head discharges the liquid, in the liquid chamber, maintained at the positive pressure from the nozzle.

### CROSS-REFERENCE TO RELATED APPLICATION

This patent application is based on and claims priority pursuant to 35 U.S.C. § 119(a) to Japanese Patent Application No. 2025-041671, filed on Mar. 14, 2025, in the Japan Patent Office, the entire disclosure of which is hereby incorporated by reference herein.

### BACKGROUND

### Technical Field

The present disclosure relates to a liquid discharge system and a liquid discharge method.

### Related Art

A bump forming apparatus has been developed that dispenses a liquid metal or a conductor paste, such as molten solder, to form a metal bump on a semiconductor chip.

For example, a bump forming apparatus includes a diaphragm that stores molten solder. The bump forming apparatus deforms the diaphragm and pressurizes the molten solder, thus discharging the molten solder from nozzles.

### SUMMARY

The present disclosure described herein provides a liquid discharge system including a liquid discharge head and a pressurizer. The liquid discharge head includes a nozzle member having a nozzle to discharge a liquid; a liquid chamber member having a liquid chamber communicating with the nozzle and storing the liquid to be supplied to the nozzle; and an actuator to deform the liquid chamber to discharge the liquid in the liquid chamber from the nozzle. The pressurizer applies pressure to the liquid in the liquid chamber to maintain the liquid in the liquid chamber at a positive pressure to perform a pressurizing operation. The liquid discharge head discharges the liquid, in the liquid chamber, maintained at the positive pressure from the nozzle.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram of a discharge unit used in a bump formation system;

FIG. 2 is an external view of a liquid discharge head;

FIG. 3 is a cross-sectional view of the liquid discharge head taken along line X-X in FIG. 2;

FIG. 4 is a graph of the relationship between surface tension and Laplace pressure of a liquid;

FIG. 5 is a graph of the relationship between a nozzle-hole radius and Laplace pressure of a liquid in the nozzle hole;

FIG. 6 is a diagram illustrating an overall configuration of the bump formation system in FIG. 1;

FIG. 7 is a control block diagram of a bump formation system;

FIG. 8 is a flowchart of a method of discharging molten solder;

FIG. 9A is a diagram of a meniscus profile of a liquid maintained under depressurization, i.e., at a negative pressure;

FIG. 9B is a diagram of a meniscus profile of a liquid maintained under pressurization, i.e., at a positive pressure;

FIG. 10 is a diagram illustrating a waveform of a voltage applied during discharge;

FIG. 11 is a diagram illustrating a waveform of a voltage applied during discharge;

FIG. 12 is a plan view of a line-type discharge device;

FIG. 13 is a plan view of a serial-type discharge device;

FIG. 14 is a cross-sectional view of a liquid discharge head; and

FIG. 15 is a diagram of a damper mechanism for maintaining a liquid chamber at a negative pressure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

According to one aspect of the present disclosure, a liquid having a high surface tension can also be discharged satisfactorily.

In the following description, a liquid discharge system and a liquid discharge method according to an embodiment are described, using a bump formation system that forms bumps by dispensing molten solder as an example. In the drawings for illustrating embodiments of the present disclosure, like reference signs are assigned to elements such as components and parts that have a like function or a like shape as far as distinguishable, and descriptions of such elements may be omitted once the description is provided.

### Configuration of Discharge Mechanism of Bump Formation System

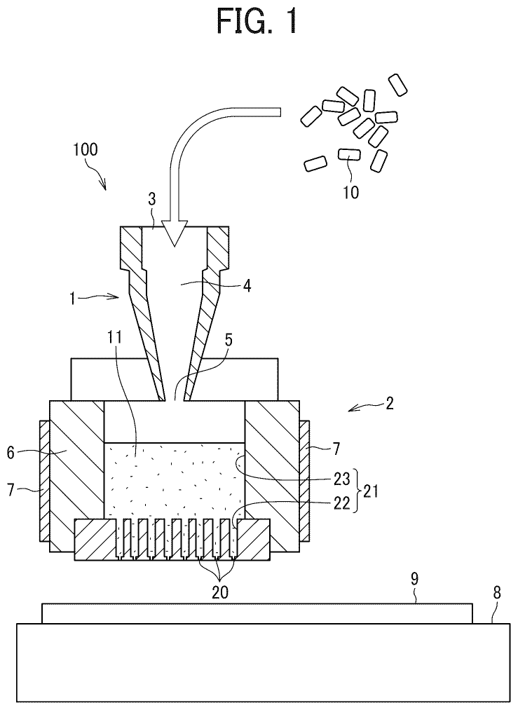

FIG. 1 is a schematic diagram of a discharge unit used in a bump formation system 100.

As illustrated in FIG. 1, the bump formation system 100 includes, as a discharge unit for discharging molten solder, a unit including a feeder 1 that supplies solder and a discharge device 2 that discharges molten solder.

The feeder 1 includes an inlet 3 into which a pellet-shaped solid solder 10 is charged, a solder storage portion 4 that stores the solder 10 charged through the inlet 3, and an outlet 5 through which the solder is supplied from the solder storage portion 4 to the discharge device 2.

The discharge device 2 includes a liquid discharge head 6 and a heater 7. The liquid discharge head 6 includes multiple nozzles 20 through which molten solder 11 is discharged, and a liquid chamber 21 that stores the molten solder 11. In this case, the liquid chamber 21 includes multiple individual liquid chambers 22 respectively communicating with the multiple nozzles 20 and a common liquid chamber 23 communicating with the multiple individual liquid chambers 22.

The heater 7 is placed on an outer surface of the liquid discharge head 6.

After the solid solder 10 charged into the feeder 1 is supplied from the feeder 1 to the liquid discharge head 6, the solder 10 is heated by the heater 7 in the common liquid chamber 23. The solid solder 10 is heated to, for example, a temperature of 200° C. and melted to become molten solder 11.

The molten solder 11 is supplied from the common liquid chamber 23 to the nozzles 20 through the individual liquid chambers 22, respectively. Thus, the individual liquid chambers 22 and the nozzles 20 are filled with the molten solder 11. When forming bumps on a substrate 9, the substrate 9 and the nozzles 20 are arranged to face each other as illustrated in FIG. 1 by moving the discharge device 2 or a table 8 on which the substrate 9 is placed. With this arrangement, the molten solder 11 is discharged in the form of droplets from the nozzles 20, forming granular solder bumps on the substrate 9.

### Configuration of Liquid Discharge Head

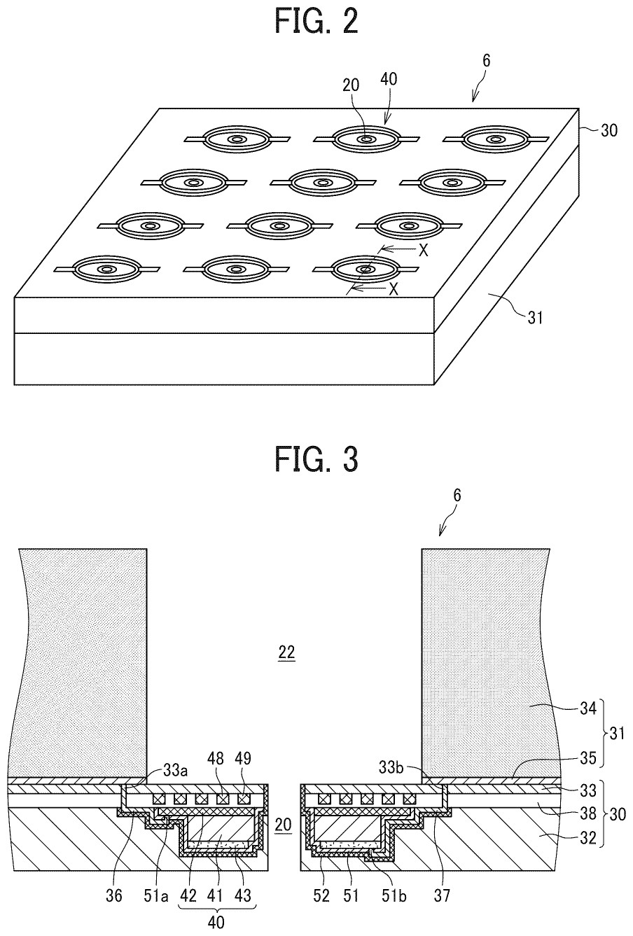

FIG. 2 is an external view of a liquid discharge head 6. FIG. 3 is a cross-sectional view of the liquid discharge head 6 taken along line X-X in FIG. 2.

The configuration of the liquid discharge head 6 is described with reference to FIGS. 2 and 3.

As illustrated in FIG. 2, the liquid discharge head 6 includes a nozzle hole member 30 having multiple nozzles 20, and a liquid chamber member 31 stacked on the nozzle hole member 30. The liquid discharge head 6 is a nozzle-vibration-type liquid discharge head. Each piezoelectric element 40 is annularly arranged around a nozzle 20. By driving the piezoelectric elements 40, peripheries of the nozzles 20 are vibrated to discharge molten solder. The arrangement of the piezoelectric elements 40 is not limited to the above-described arrangement in which each piezoelectric element 40 is continuously disposed around its corresponding nozzle 20. Each piezoelectric element 40 may be intermittently disposed around its corresponding nozzle 20.

Note that the nozzle 20 may be referred to also as a nozzle hole.

As illustrated in FIG. 3, the nozzle hole member 30 includes a nozzle plate 32 in which the piezoelectric elements 40 are disposed, a vibration diaphragm 33, and a first insulating film 38 interposed between the nozzle plate 32 and the vibration diaphragm 33. The liquid chamber member 31 includes an individual liquid chamber member 34 that forms most of the individual liquid chamber 22, and a wiring layer 35 bonded to the individual liquid chamber member 34. In addition to the individual liquid chamber member 34 and the wiring layer 35, the liquid chamber member 31 also includes a common liquid chamber member that forms the common liquid chamber 23 (refer to FIG. 1).

The nozzle plate 32 covers the piezoelectric element 40 disposed around the nozzle 20 to protect the piezoelectric element 40 from an external load. The nozzle plate 32 is made of, for example, resin. Resins are a favorable material for the nozzle plate 32 when they can be applied by spin coating. For example, epoxy resin SU-8 and benzocyclobutene (BCB) are preferable in terms of chemical resistance.

Each of the piezoelectric elements 40 is an actuator that vibrates the nozzle hole member 30, and includes a piezoelectric body 41, and a first electrode 42 and a second electrode 43 that are coupled to the piezoelectric body 41. The piezoelectric body 41 contains lead zirconate titanate (PZT). Examples of a material of the piezoelectric body 41, include various materials, including PZT. When the piezoelectric body 41 has a drive circuit and wiring built therein, it is preferable that the material is formable at a temperature of 450° C. or lower to prevent damage to the drive circuit and the wiring. Examples of the material that is formable at a temperature of 450° C. or less include aluminum nitride (AlN). The material of the first electrode 42 and the second electrode 43 is preferably a metal having low electric resistance and low reactivity, and preferred examples thereof include platinum (Pt), iridium (Ir), and molybdenum (Mo). The piezoelectric body 41, the first electrode 42, and the second electrode 43 are covered with a second insulating film 51.

The vibration diaphragm 33 vibrates when the piezoelectric element 40 is driven. As illustrated in FIG. 3, the vibration diaphragm 33, the first insulating film 38, and the nozzle plate 32 are laminated, and the nozzle hole extends through the vibration diaphragm 33, the first insulating film 38, and the nozzle plate 32. The vibration diaphragm 33 is stacked on and bonded to a surface of the first insulating film 38, facing the individual liquid chamber 22. When the piezoelectric body 41 is driven to vibrate the vibration diaphragm 33, the periphery of the nozzle 20 vibrates. The vibration diaphragm 33 may be made of a material having at least insulating properties, such as silicon dioxide (SiO₂), silicon nitride (SiN), a metal oxide, or a resin. To obtain the discharge function by increasing the vibration of the vibration diaphragm 33, a material with a low Young's modulus is preferable. In view of the difference in linear expansion coefficient between the vibration diaphragm 33 and the liquid chamber member 31, SiO₂, which has a small difference, is preferable as the material of the vibration diaphragm 33.

The first insulating film 38 includes a heater 48 and a temperature detector 49. The heat generation of the heater 48 is controlled based on the temperature detected by the temperature detector 49. This allows the molten state of the molten solder to be appropriately maintained in the individual liquid chambers 22 and the nozzles 20. Examples of the material of the heater 48 include Mo and Pt. When the heater 48 is made of Mo or Pt, efficient heating can be achieved due to high resistivity.

The individual liquid chamber member 34 includes a silicon (Si) substrate. The wiring layer 35 is stacked on and bonded to the surface of the individual liquid chamber member 34 facing the nozzle hole member 30. The wiring layer 35 includes a wiring portion for applying a drive waveform to the first electrode 42 and the second electrode 43, and a wiring portion for applying a voltage to the heater 48 and the temperature detector 49. The wiring layer 35 forms a part of each individual liquid chamber 22. The wiring layer 35 is electrically connected to the first electrode 42 via a first lead-out wiring 36, and to the second electrode 43 via a second lead-out wiring 37. Each second insulating film 51 covering the corresponding piezoelectric element 40 includes a hole-shaped first contact 51a that connects the first lead-out wiring 36 to the first electrode 42, and a hole-shaped second contact 51b that connects the second lead-out wiring 37 to the second electrode 43. The vibration diaphragm 33 includes a hole-shaped third contact 33a that connects the first lead-out wiring 36 to the wiring layer 35, and a hole-shaped fourth contact 33b that connects the second lead-out wiring 37 to the wiring layer 35. The first lead-out wiring 36 and the second lead-out wiring 37 are covered with a third insulating film 52.

As described above, the first electrode 42 and the second electrode 43 are electrically connected to the wiring layer 35 via the first lead-out wiring 36 and the second lead-out wiring 37. This allows a predetermined drive waveform (or a voltage) to be applied to the first electrode 42 and the second electrode 43 from a drive circuit coupled to the wiring layer 35. When a drive waveform is applied from the drive circuit to the first electrode 42 and the second electrode 43, the piezoelectric body 41 is driven to vibrate the vibration diaphragm 33, pressurizing the molten solder in the individual liquid chamber 22 and discharging the molten solder from the nozzle 20.

### Technical Challenges in Bump Formation System

Technical challenges in the bump formation system are described below, using the bump formation system illustrated in FIG. 1 as an example.

In the bump formation system that pressurizes and discharges the molten solder as described above, the molten solder in each nozzle 20 is maintained with a predetermined meniscus (curved surface) for discharging the molten solder. To discharge the molten solder from the nozzle hole, a pressurizing force exceeding the Laplace pressure, which is the difference between the internal pressure and the external pressure, generated in the molten solder is applied.

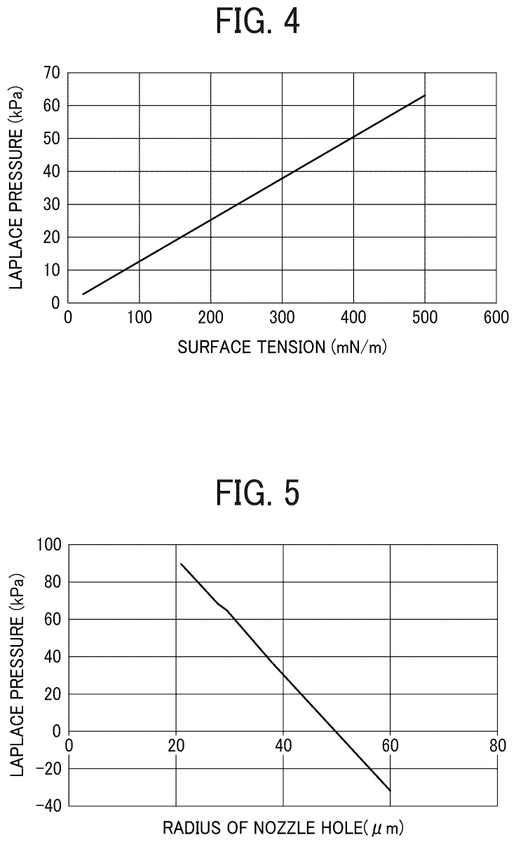

Moreover, such a Laplace pressure is generated not only in the molten solder but also in various liquids when the liquid forms a meniscus. Since the Laplace pressure varies with the surface tension of the liquid, a pressurizing force is to be applied according to the Laplace pressure. FIG. 4 is a graph of the relationship between surface tension and Laplace pressure of a liquid.

FIG. 4 is a graph of the relationship between surface tension and Laplace pressure of a liquid. More specifically, the graph in FIG. 4 presents the relationship between the surface tension and the Laplace pressure of the liquid when the nozzle-hole diameter is 30 μm.

As illustrated in FIG. 4, the Laplace pressure on the vertical axis increases as the surface tension on the horizontal axis increases. The relationship between the surface tension and the Laplace pressure is not limited to the nozzle-hole diameter of 30 μm, and similarly applies to other nozzle-hole diameters. As the surface tension of the liquid to be discharged increases, a greater pressurizing force is involved.

The Laplace pressure also changes depending on the diameter of the nozzle hole for discharging the liquid, in addition to the surface tension. FIG. 5 is a graph of the relationship between a nozzle-hole radius and Laplace pressure of a liquid in the nozzle holes

FIG. 5 is a graph illustrating the relationship between a nozzle-hole radius and Laplace pressure of a liquid in the nozzle hole when the surface tension of the liquid is 500 millinewton per meter (mN/m).

As illustrated in FIG. 5, the Laplace pressure on the vertical axis increases as the radius of the nozzle hole on the horizontal axis decreases. The relationship between the nozzle-hole radius and the Laplace pressure is not limited to a surface tension of 500 mN/m, and similarly applies to other surface tensions. As the diameter of the nozzle hole for discharging the liquid decreases, a greater pressurizing force is involved.

As described above, since the Laplace pressure generated in the liquid increases as the surface tension of the liquid increases and increases as the diameter of the nozzle hole decreases, a particularly great pressurizing force is to be applied to discharge a liquid having high surface tension from a small-diameter nozzle hole. For example, typical inks used for image formation have a surface tension greater than or equal to 30 mN/m and less than or equal to 40 mN/m, whereas molten metals have a surface tension greater than or equal to 500 mN/m and less than or equal to 600 mN/m. That is, the surface tension of the molten metal is 10 times or greater than the surface tension of the ink. As a result, when discharging the molten metal, applying the same level of pressure as that used to discharge the ink may fail to discharge the molten metal. Another approach is to increase the voltage applied to the piezoelectric element to increase the pressurizing force for discharging the molten metal. However, this approach uses a piezoelectric element that withstands the higher voltage and may force a design change of the liquid discharge head. If a design change is to be conduced, a liquid discharge head having the same configuration as a typical liquid discharge head cannot be used. This may increase the cost associated with the design change and increase the size of the liquid discharge head. In addition, this method also increases power consumption because a high voltage is applied.

To address such a situation, a liquid discharge system and a liquid discharge method are proposed as follows. In the following description, a liquid discharge system and a liquid discharge method according to an embodiment are described, using the bump formation system 100 illustrated in FIG. 1 as an example.

### Overall Configuration of the Bump Formation System

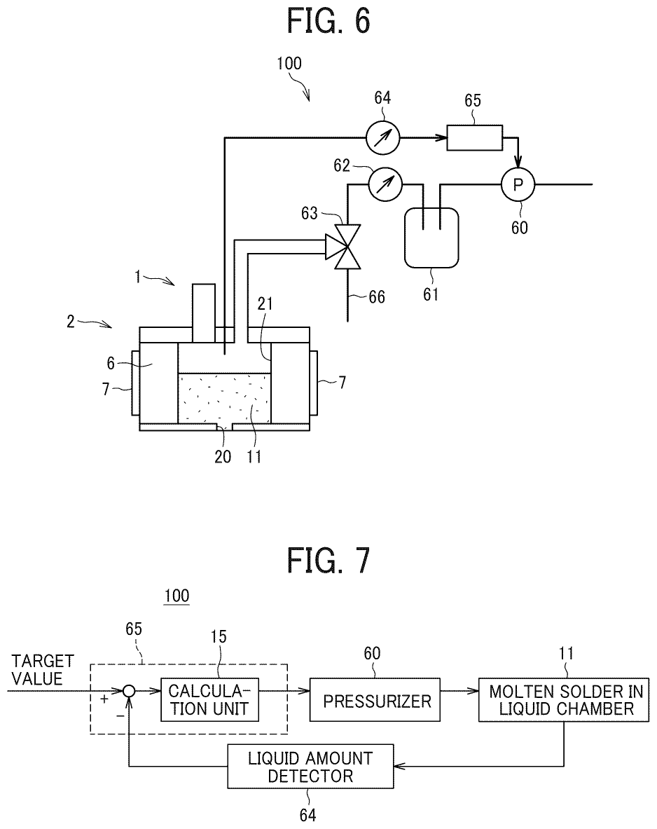

FIG. 6 is a diagram illustrating an overall configuration of the bump formation system 100 in FIG. 1.

As illustrated in FIG. 6, the bump formation system 100 includes a pressurizer 60, a buffer tank 61, a pressure detector 62, a switching valve 63, a liquid amount detector 64, and a pressurization controller 65, in addition to the feeder 1 and the discharge device 2 described above.

The pressurizer 60 includes a pressurizing pump that pressurizes a gas such as air to generate pressurized gas. The pressurizer 60 is coupled to the liquid chamber 21 of the liquid discharge head 6 via the buffer tank 61 and the switching valve 63.

The buffer tank 61 is a tank that functions as a pressurized gas storage unit that temporarily stores the pressurized gas in order to prevent pressure fluctuations of the pressurized gas supplied from the pressurizer 60. The pressure detector 62 is placed between the buffer tank 61 and the switching valve 63, to measure the pressure of the pressurized gas.

The switching valve 63 is placed between the buffer tank 61 and the liquid discharge head 6, and switches a flow path communicating with the liquid chamber 21. Switching the switching valve 63 switches between a state in which the liquid chamber 21 communicates with the pressurizer 60 and a state in which the liquid chamber 21 communicates with an atmosphere opening portion 66.

The liquid amount detector 64 detects the amount of the molten solder 11 in the liquid chamber 21. In this case, the liquid amount detector 64 includes a liquid level sensor that detects the liquid level height of the molten solder 11 to detect the amount of the molten solder 11 in the liquid chamber 21. The liquid amount detector 64 may detect the liquid amount by a method other than detecting the liquid level.

The pressurization controller 65 controls the pressurizing operation of the pressurizer 60 based on the amount of the molten solder 11 detected by the liquid amount detector 64.

FIG. 7 is a control block diagram of the bump formation system 100.

As illustrated in FIG. 7, the pressurization controller 65 includes a calculation unit 15. The calculation unit 15 is implemented by processing performed by a central processing unit (CPU), and calculates a control amount for the pressurizing operation of the pressurizer 60 based on the amount (liquid level height) of the molten solder 11 detected by the liquid amount detector 64 and a target liquid level height. The pressurization controller 65 controls the pressurizing operation of the pressurizer 60 based on the calculated control amount of the pressurization operation.

### Method of Discharging Molten Solder

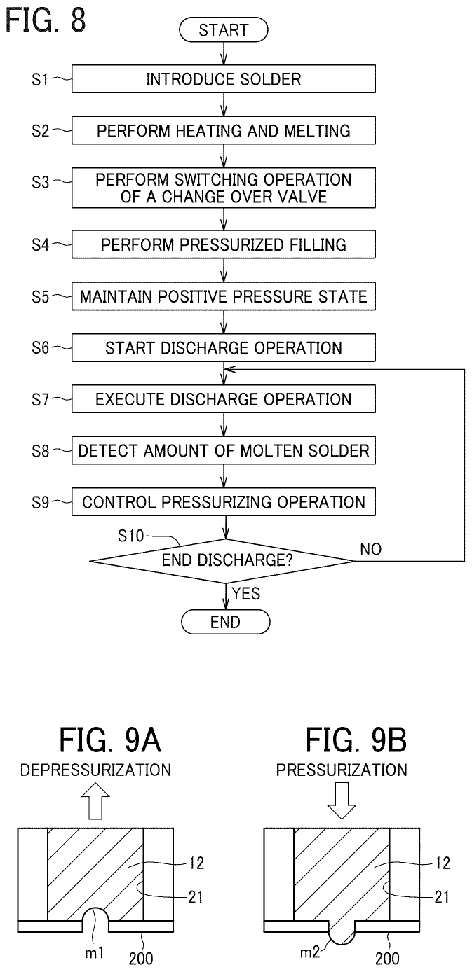

The method of discharging molten solder is described below with reference to the flowchart of FIG. 8.

In the bump formation system 100, when molten solder is to be discharged, as illustrated in FIG. 8, solid solder as a material of the molten solder is first charged into the feeder 1 (Step 1 in FIG. 8). The heater 7 heats and melts the solid solder supplied into the liquid chamber 21 of the liquid discharge head 6 (Step 2 in FIG. 8). At this time, the switching valve 63 in FIG. 6 switches the liquid chamber 21 to communicate with the atmosphere opening portion 66, and the solid solder is heated under atmospheric pressure.

Thereafter, with the solid solder completely melted, the switching valve 63 switches the flow path so that the liquid chamber 21 communicates with the pressurizer 60 (Step 3 in FIG. 8). Then, the pressurizer 60 is driven to supply pressurized gas to the liquid chamber 21 for a certain period while the pressurization controller 65 controls the pressurizing operation of the pressurizer 60. This configuration allows the molten solder in the liquid chamber 21 to be pressurized by a preset pressurizing force, filling the nozzles 20 with the molten solder (Step 4 in FIG. 8). At this stage, a portion of the molten solder is discharged from each nozzle 20, discharging air bubbles contained in the molten solder with the molten solder.

After the filling with the molten solder is completed, the pressurization controller 65 controls the pressurizing operation of the pressurizer 60 again, and changes the pressurizing force of the pressurizer 60 to a pressurizing force smaller than the pressurizing force used in pressurized filling in which the molten solder in the liquid chamber 21 is pressurized to fill the nozzles 20 with the molten solder. Then, the pressurizer 60 pressurizes the molten solder in the liquid chamber 21 with the changed pressurizing force, and maintains the molten solder in the liquid chamber 21 and the nozzles 20 at a predetermined positive pressure (Step 5 in FIG. 8).

Upon receiving an instruction to start the discharge operation (Step 6 in FIG. 8), the bump formation system 100 drives the piezoelectric elements 40 to discharge the molten solder from the nozzles 20 with the molten solder in the liquid chamber 21 and the nozzles 20 maintained at a positive pressure (Step 7 in FIG. 8).

When the amount of the molten solder in the liquid chamber 21 decreases with the discharge of the molten solder from the nozzles 20, the liquid amount detector 64 of FIG. 6 detects the amount of the molten solder in the liquid chamber 21 (Step 8 of FIG. 8). In Step 9 of FIG. 8, the pressurization controller 65 controls the pressurizing operation of the pressurizer 60 again based on the amount of the molten solder detected by the liquid amount detector 64 in FIG. Step 8. As a result, the molten solder in the liquid chamber 21 and the nozzle 20 is maintained at a predetermined positive pressure.

When the bump formation system 100 does not end the discharge, i.e., the discharge is continued (NO in Step 10 of FIG. 8), the discharge device 2 performs the discharge operation with the molten solder maintained at a positive pressure (Step 7 of FIG. 8). Further, the liquid amount detector 64 detects the amount of the molten solder after the discharge of the molten solder in Step 7 (Step 8 in FIG. 8). Then, in Step 9 of FIG. 8, the pressurization controller 65 controls the pressurizing operation of the pressurizer 60 again based on the amount of the molten solder detected by the liquid amount detector 64 in FIG. Step 8. Thereafter, when the discharge is continued, the same steps are repeated. When the bump formation system 100 ends the discharge, i.e., the discharge is no continued (YES in Step 10 of FIG. 8), the discharge operation ends.

As described above, in the bump formation system 100, the pressurizer 60 pressurizes the molten solder in the liquid chamber 21 and the nozzles 20 and maintains the molten solder at a positive pressure before the discharge of the molten solder. This allows even a liquid having high surface tension, such as molten solder, to be discharged with a low pressurizing force. That is, the liquid discharge system (e.g., the bump formation system 100) pressurizes the liquid in advance and maintains the liquid at a positive pressure prior to discharge, so that the pressurizing force for discharge can be reduced.

In a system that discharges a liquid having low surface tension, such as ink used for image formation, pressurizing the liquid prior to discharge may cause the liquid to leak from the nozzle holes. Accordingly, the liquid is typically maintained at a negative pressure. In such a discharge system, as illustrated in FIG. 9A, the liquid 12 in the liquid chamber 21 forms a concave meniscus m1 that is recessed inward from a nozzle surface 200 due to the negative pressure. However, in the liquid discharge system according to an embodiment of the present disclosure, the liquid 12 in the liquid chamber 21 is pressurized and maintained at a positive pressure prior to discharge, thus forming a convex meniscus m2 that protrudes outward from the nozzle surface 200 as illustrated in FIG. 9B.

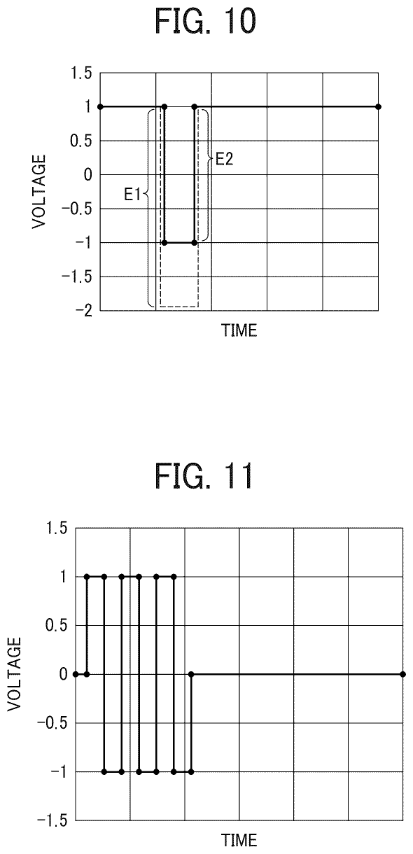

This configuration allows the liquid discharge system to discharge a liquid having high surface tension, such as molten solder, with a low pressurizing force. Thus, power consumption of an actuator, such as a piezoelectric element, can be reduced during the discharge operation. When the liquid is discharged after the liquid is set to a negative pressure, a high voltage E1 is applied to the actuator upon discharge, as indicated by the broken line in FIG. 10. In contrast, when the liquid is discharged after the liquid is set to a positive pressure as in an embodiment of the present disclosure, the liquid can be discharged by applying a low voltage E2, as indicated by the solid line in FIG. 10. In other words, applying a voltage comparable to that used to discharge a liquid having low surface tension enables discharge of a liquid having high surface tension.

Accordingly, with this configuration, a liquid discharge head having the same configuration as a conventional liquid discharge head can be used as a liquid discharge head for discharging a liquid having high surface tension.

As described above, in the liquid discharge system, the liquid within the liquid chamber and the nozzle holes is pressurized in advance and held at a positive pressure prior to discharge. This allows discharge of a liquid having a high surface tension. In addition, by using a pressurizer separate from the actuator that pressurizes the liquid during discharge to pressurize the liquid in advance and maintain the liquid at a positive pressure, the voltage applied to the actuator during discharge can be reduced, reducing power consumption.

Japanese Unexamined Patent Application Publication No. 2012-61656 describes a method of pressurizing ink in an inkjet head by using a pressurizer provided in the head. However, the method aims to shorten an ink suction operation by pressurizing the ink in the head simultaneously with suction of the ink, and is not a method employed to discharge a liquid having high surface tension as in an embodiment of the present disclosure. In contrast, in the present disclosure, the liquid to be discharged is maintained at a positive pressure, enabling the liquid having high surface tension to be discharged with a low pressurizing force.

The liquid discharge system controls the pressurizing operation of the pressurizer based on the amount of the liquid in the liquid chamber. This allows the liquid to be maintained at a predetermined positive pressure regardless of changes in the amount of the liquid in the liquid chamber. That is, when the amount of the liquid in the liquid chamber decreases due to discharge of the liquid, the pressurizing force varies even with the same pressurizing operation, so that the liquid may no longer be maintained at the predetermined positive pressure. In an embodiment of the present disclosure, however, the pressurizing operation of the pressurizer is controlled based on the amount of the liquid detected after discharge, so that the liquid can be maintained at the predetermined positive pressure. Accordingly, since the liquid in the nozzle holes can maintain a predetermined meniscus, stable discharge of the liquid is achieved. The pressurizing operation based on the amount of the liquid in the liquid chamber after discharge may be controlled after each discharge, or after multiple discharges.

Further, since the liquid discharge system maintains the liquid at a positive pressure, the liquid discharge system does not include a negative-pressure generator for maintaining the liquid at a negative pressure. For example, an ink-jet image forming apparatus that discharges ink to form an image may include a damper mechanism 500 to maintain at a negative pressure prior to discharge. The damper mechanism 500 urges a damper member 502 as illustrated in FIG. 15 with a spring 501 to generate a negative pressure in a liquid chamber 300. However, the liquid discharge system may not include such a damper mechanism 500. By eliminating such a damper mechanism (e.g., a negative-pressure generator), the liquid discharge system can be made more compact and lower in cost.

In the liquid discharge system according to an embodiment of the present disclosure, a pressurizer that pressurizes the liquid to a positive pressure is used separately from the actuator, such as the piezoelectric element that discharges the liquid. This arrangement involves installation cost and space for an additional pressurizer. However, in a typical liquid discharge system, a pressurizer that pressurizes the liquid when filling the nozzle holes with the liquid is often provided. Thus, it is preferable to set the liquid to a positive pressure using such a pressurizer used for pressurized filling. This eliminates the addition of an additional pressurizer, reducing the manufacturing cost and preventing an increase in the overall size of the liquid discharge system. The pressurizer is not limited to a pressurizer used for pressurized filling of the liquid, and may be a pressurizer used to discharge the liquid from the nozzle hole during maintenance, such as cleaning.

The pressurizing force applied by the pressurizer to maintain the liquid at a positive pressure can be adjusted as appropriate depending on the type of liquid. Particularly when a molten metal, such as molten solder, is discharged, the pressurizing force applied by the pressurizer is preferably 50 kilopascal (kPa) or higher. By setting the pressurizing force applied by the pressurizer to 50 kPa or higher, even a liquid having high surface tension, such as a molten metal having a surface tension of greater than or equal to 500 mN/m and less than or equal to 600 mN/m, can be discharged with a relatively low pressure.

Further, as in the example of FIG. 11, the voltage applied to the actuator for discharge may be applied multiple times in succession in accordance with the resonance occurring in the liquid chamber. In this case, since the displacement (vibration amplitude) of the vibration diaphragm 33 (refer to FIG. 3) can be increased, even a liquid having high surface tension is easily discharged. In addition, when the voltage is repeatedly applied in accordance with the resonance occurring in the liquid chamber, the displacement of the meniscus of the liquid held in the nozzle hole is amplified with each application of the voltage. Thus, the liquid can be discharged with a voltage lower than the voltage used when the voltage is applied only as illustrated in FIG. 10. That is, the discharge method as illustrated in FIG. 11 allows the applied voltage to be reduced. In addition, this configuration allows discharge of a liquid having a higher surface even at a voltage of the same level comparable to that in FIG. 10. The magnitude of the voltage applied repeatedly may be the same or may be different for each application.

In addition, in a case where a molten metal such as molten solder is used as the liquid, an inert gas such as nitrogen is preferably used as the pressurized gas supplied from the pressurizer to the liquid chamber. By using an inert gas as the pressurized gas, oxidation of the molten metal in the liquid chamber is prevented, preventing discharge defects caused by oxides contained in the molten metal.

In the description above, the liquid discharge system and the liquid discharge method are described. The present disclosure is not limited to the above-described embodiments. For example, elements and/or features of different illustrative embodiments may be combined with each other and/or substituted for each other within the scope of the present disclosure.

In the above embodiments, a bump formation system that forms bumps by discharging molten solder has been described as one example of the liquid discharge system. However, the above-described configuration is also applicable to liquid discharge systems that discharge, in addition to molten solder, other molten metals; metal materials that are liquid or paste at room temperature, including metals or alloys; and liquids other than metal materials. The liquid used in the liquid discharge system and the liquid discharge method may be, as long as the liquid can be maintained at a positive pressure, not only a molten metal such as molten solder but also a liquid other than a metal material, and the type of the liquid is not limited. However, since a configuration according to an embodiment of the present disclosure can provide particularly significant effects when applied to discharge a liquid having high surface tension, the configuration according to an embodiment of the present disclosure is preferably applied, for example, to discharge a liquid having a surface tension of 300 mN/m or higher.

In addition, in terms of providing the effects more effectively, a configuration according to an embodiment of the present disclosure is preferably applied to a configuration having nozzle holes with a small diameter. For example, when a configuration according to an embodiment of the present disclosure is applied to a configuration in which the diameter of the nozzle hole is 100 μm or less (the radius is 50 μm or less), a larger effect can be expected. A larger effect can also be expected when the configuration is applied to a configuration in which the diameter of the nozzle hole is 60 μm or less (the radius is 30 μm or less), which is smaller than the above.

The discharge device used in the liquid discharge system may not include a heater (e.g., the heater 7 in FIG. 1 and the heater 48 in FIG. 3) that heats the liquid and may include a single nozzle hole instead of multiple nozzle holes. The discharge device may be a line-type device that discharges liquid while the liquid discharge head remains stationary, or a serial-type device that discharges liquid while the liquid discharge head is moved. The following briefly describes the configuration of a different type of discharge device.

### Configuration of Line-Type Discharge Device

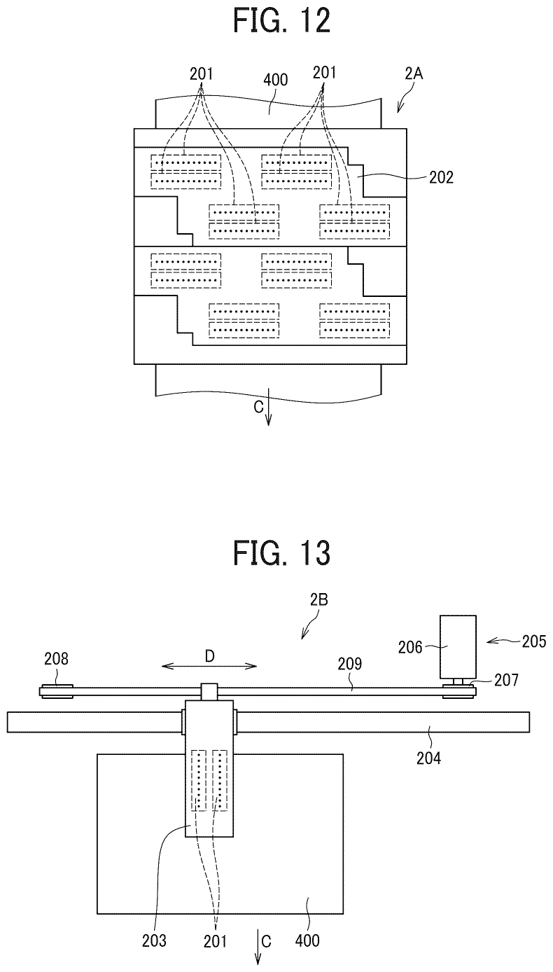

FIG. 12 is a plan view of a line-type discharge device 2A.

The line-type discharge device 2A illustrated in FIG. 12 includes multiple liquid discharge heads 201 and a head holder 202 that holds the multiple liquid discharge heads 201. The head holder 202 is fixed to a frame of the apparatus body. In this case, when the object 400, such as a substrate, is conveyed in the conveyance direction C in FIG. 12 to a position facing the liquid discharge heads 201, the liquid discharge heads 201 discharge the liquid. At this time, the liquid discharge heads 201 discharge the liquid without moving relative to the object 400 being conveyed.

### Configuration of Serial-Type Discharge Device

The following describes the configuration of the serial-type discharge device.

FIG. 13 is a plan view of a serial-type discharge device 2B.

The serial-type discharge device 2B illustrated in FIG. 13 includes a carriage 203 mounting multiple liquid discharge heads 201, a guide member 204 (e.g., a guide rod) that guides the carriage 203 in a main scanning direction D orthogonal to a movement direction (or a conveyance direction) C of an object 400, and a drive device 205 that moves the carriage 203.

The drive device 205 includes, for example, a motor 206 and a timing belt 209. The motor 206 serves as a driving source. The timing belt 209 is looped around a drive pulley 207 and a driven pulley 208. As the motor 206 is driven and the drive pulley 207 is rotated, the timing belt 209 circumferentially moves. Accordingly, the carriage 203 is moved in the main scanning direction D along the guide member 204.

As illustrated in FIG. 13, when the object 400 is conveyed in the direction of the arrow C and reaches a predetermined position, the movement of the object 400 is temporarily stopped. Then, liquid is discharged from the liquid discharge head 201 while the carriage 203 reciprocates in the main scanning direction D. Thereafter, the movement of the object 400 is restarted, and the object 400 is intermittently moved in the direction of arrow C. Each time the movement of the object 400 stops, the reciprocating movement and the discharge operation of the carriage 203 are repeated. As a result, the liquid is sequentially discharged onto the object 400.

The liquid discharge head according to an embodiment of the present disclosure is not limited to a nozzle vibration type liquid discharge head, and may be a liquid discharge head of another type.

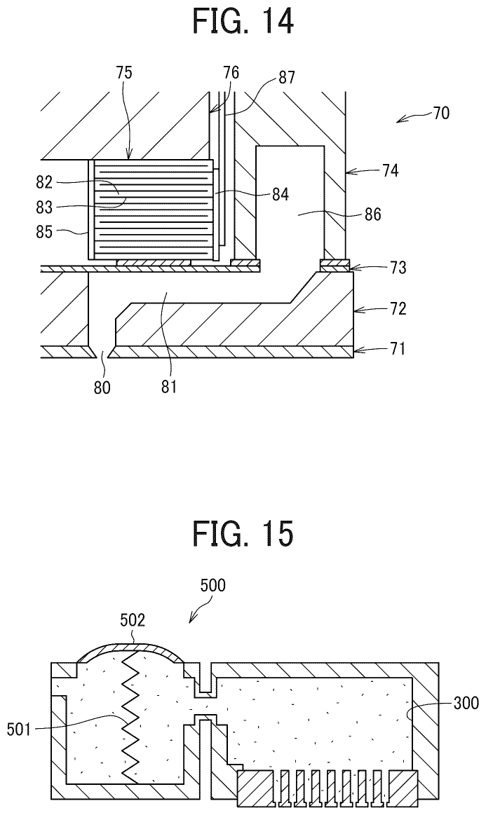

For example, as illustrated in FIG. 14, the liquid discharge head according to an embodiment of the present disclosure may be a liquid discharge head 70 that discharges liquid by deforming a vibration plate 73 with a piezoelectric element 75 to pressurize the liquid in an individual liquid chamber 81. The following describers the configuration of the liquid discharge head 70.

The liquid discharge head 70 illustrated in FIG. 14 includes a nozzle plate 71, an individual liquid chamber member 72, a vibration plate 73, a common liquid chamber member 74, a piezoelectric element 75, and a base member 76.

The nozzle plate 71 has nozzle holes 80 for discharging liquid. Although only one nozzle hole 80 is illustrated in FIG. 14, multiple nozzle holes 80 are provided in a direction orthogonal to the plane of the sheet of FIG. 14.

The individual liquid chamber member 72 includes multiple individual liquid chambers 81 respectively communicating with the multiple nozzle holes 80. The common liquid chamber member 74 includes a common liquid chamber 86 that commonly communicates with the multiple individual liquid chambers 81. When liquid is supplied from an external supply device into the common liquid chamber 86, the liquid is supplied from the common liquid chamber 86 to each individual liquid chamber 81.

The vibration plate 73 is a deformable member interposed between the individual liquid chamber member 72 and the common liquid chamber member 74. The vibration plate 73 is bonded to the individual liquid chamber member 72, forming a deformable vibration wall portion that partitions the individual liquid chamber 81. The deformable vibration wall portion is provided with the piezoelectric element 75 as an actuator that deforms the vibration plate 73.

The piezoelectric element 75 is displaced in the stacking direction in accordance with a drive waveform of a electric signal applied from a drive circuit (e.g., a driver IC). The piezoelectric element 75 is disposed between the vibration plate 73 and the base member 76, and is supported by the base member 76 disposed on an opposite side of the piezoelectric element 75 from the vibration plate 73. The piezoelectric element 75 is formed by alternately stacking, for example, piezoelectric layers 82 of lead zirconate titanate (PZT) having a thickness of 10 to 50 μm and internal electrode layers 83 of silver palladium (AgPd) having a thickness of several μm. The internal electrode layer 83 is coupled to an individual electrode 84 and a common electrode 85. Further, the drive circuit is coupled to the individual electrode 84 through a flexible wiring member 87.

The drive circuit selectively applies a drive waveform to the piezoelectric element 75 for each individual liquid chamber 81. When a drive waveform is applied from the drive circuit to the piezoelectric element 75, the piezoelectric element 75 is displaced in the stacking direction, deforming the vibration plate 73. Accordingly, the liquid in the individual liquid chamber 81 is pressurized and discharged through the nozzle hole 80. The actuator that is driven to discharge the liquid is not limited to the electromechanical conversion element such as the piezoelectric element 75, and may be a thermomechanical conversion element such as a bimetal.

Even in such a liquid discharge head 70, the configuration according to an embodiment of the present disclosure enables successful discharge even with a liquid having high surface tension. That is, by pressurizing the liquid in the individual liquid chambers 81 and in the nozzle holes 80 so as to maintain positive pressure before the liquid is discharged, even a liquid having high surface tension can be discharged with a low pressurizing force.

A liquid discharge system includes a liquid discharge head (6) and a pressurizer (60). The liquid discharge head (6) includes a nozzle member (30) having a nozzle (20) to discharge a liquid; a liquid chamber member (31) having a liquid chamber (22) communicating with the nozzle and storing the liquid to be supplied to the nozzle; and an actuator (40) to deform the liquid chamber to discharge the liquid in the liquid chamber from the nozzle. The pressurizer (60) applies pressure to the liquid in the liquid chamber (21) to maintain the liquid in the liquid chamber (21) at a positive pressure to perform a pressurizing operation. The liquid discharge head discharges the liquid, in the liquid chamber, maintained at the positive pressure from the nozzle.

The liquid discharge system further includes a liquid amount detector (64) to detect a liquid amount of the liquid in the liquid chamber (21); and circuitry (65) configured to control the pressurizer (60) to perform the pressurizing operation based on the liquid amount in the liquid chamber detected by the liquid amount detector (64).

The nozzle member includes the actuator (40) inside the nozzle member, and the actuator vibrates the nozzle member to discharge the liquid in the liquid chamber from the nozzle.

The pressurizer applies pressure to the liquid in the liquid chamber with a pressurizing force of 50 kilopascal (kPa) or higher to maintain the liquid in the liquid chamber at the positive pressure.

The liquid discharge head has the nozzle (20) having a diameter of 100 μm or less.

The liquid discharge system further includes a heater (7) on an outer surface of the liquid discharge head, to heat the liquid in the liquid chamber (21).

The heater (7) heats the liquid in the liquid chamber to a temperature of 200° C. or higher.

The liquid discharge head (6) discharges the liquid having a surface tension of 300 mN/m or higher from the nozzle.

The liquid discharge head discharges the liquid including a liquid or paste metal material containing a metal or an alloy from the nozzle.

The liquid discharge head discharges the liquid including molten solder from the nozzle.

The pressurizer supplies an inert gas to the liquid chamber to pressurize the liquid in the liquid chamber.

The circuitry is further configured to apply a voltage to the actuator (40) multiple times in succession to discharge the liquid in the liquid chamber (21) through the nozzle (20) while the pressurizer maintains the liquid in the liquid chamber at the positive pressure.

A liquid discharge method of discharging a liquid includes deforming a liquid chamber (21) of a liquid discharge head, the liquid chamber communicating with a nozzle and storing the liquid to be supplied to the nozzle; and applying pressure to the liquid in the liquid chamber (21) to maintain the liquid in the liquid chamber (21) at a positive pressure to perform a pressurizing operation to discharge the liquid in the liquid chamber from the nozzle. The liquid discharge head discharges the liquid, in the liquid chamber, maintained at the positive pressure from the nozzle.

The pressurizer maintains the liquid in the liquid chamber (21) at the positive pressure, to maintain the liquid in the nozzle to form a convex meniscus that protrudes outward from a nozzle surface of the nozzle member.

The above-described embodiments of the present disclosure include at least the following aspects.

### Aspect 1

A liquid discharge system includes a liquid discharge head (6), a liquid amount detector (64), and a pressurizer (60), and circuitry (a pressurization controller 65). The liquid discharge head (6) includes a nozzle hole member (30) having nozzle holes (20) through which a liquid is dischargeable; a liquid chamber member (31) forming a liquid chamber (21), the liquid chamber (21) communicating with the nozzle holes and that stores the liquid; and an actuator (40) to vibrate the nozzle hole member (30) to pressurize the liquid stored in the liquid chamber (21) to discharge the liquid from the liquid chamber (21) through the nozzle holes (20). The liquid amount detector (64) detects an amount of the liquid in the liquid chamber (21). The pressurizer (60) pressurizes the liquid in the liquid chamber (21) to maintain the liquid at a positive pressure. The circuitry (65) is configured to control a pressurizing operation of the pressurizer (60) based on the amount of the liquid in the liquid chamber detected by the liquid amount detector (64).

### Aspect 2

A liquid discharge system includes a liquid discharge head (6) including a nozzle hole member (30) having nozzle holes (20) through which a liquid is dischargeable; a liquid chamber member (31) forming a liquid chamber (21), the liquid chamber (21) communicating with the nozzle holes and that stores the liquid; and an actuator (40) to pressurize the liquid stored in the liquid chamber (21) to discharge the liquid from the liquid chamber (21) through the nozzles 20. The liquid discharge system further includes a liquid amount detector (64) to detect an amount of the liquid in the liquid chamber (21); and a pressurizer (60) to pressurize the liquid in the liquid chamber (21) to maintain the liquid at a positive pressure.

### Aspect 3

According to Aspect 3, in Aspect 1 or 2, a nozzle hole member having the nozzle hole is vibrated by the actuator, and the liquid is discharged from the nozzle hole.

### Aspect 4

According to Aspect 4, in any one of Aspects 1 to 3, a pressurizing force of the pressurizer that holds the liquid in a positive-pressure state is equal to or greater than a 50 kPa.

### Aspect 5

According to Aspect 5, in any one of Aspects 1 to 4, each of the nozzle holes has a diameter of 100 μm or less.

### Aspect 6

According to Aspect 6, in any one of Aspects 1 to 5, the liquid ejecting apparatus further includes a heater that heats the liquid in the liquid chamber.

### Aspect 7

In Aspect 7 according to Aspect 6, the heater heats the liquid to a temperature of 200° C. or higher.

### Aspect 8

In Aspect 8 according to any one of Aspects 1 to 9, the liquid is a liquid having a surface tension of 300 mN/m or higher.

### Aspect 9

According to Aspect 9, in any one of Aspects 1 to 8, the liquid discharge system discharges a liquid or paste metal material containing a metal or an alloy.

### Aspect 10

According to Aspect 10, in any one of Aspects 1 to 8, the liquid is molten solder.

### Aspect 11

In Aspect 11 according to any one of Aspects 1 to 10, the pressurizer pressurizes the liquid by supplying an inert gas into the liquid chamber.

### Aspect 12

According to Aspect 12, in any one of Aspects 1 to 11, the circuitry is further configured to apply a voltage to the actuator multiple times in succession, with the liquid maintained at a positive pressure by the pressurizer, to discharge the liquid in the liquid chamber through the nozzle holes.

### Aspect 13

A method of discharging a liquid includes detecting an amount of the liquid in a liquid chamber (21) of a liquid discharge head (6); controlling a pressurizing operation of a pressurizer (60) based on the amount of the liquid in the liquid chamber detected, to maintain the liquid in the liquid chamber, at a positive pressure; and discharging the liquid maintained at a positive pressure from the liquid chamber through nozzle holes of the liquid chamber

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

The functionality of the elements disclosed herein may be implemented using circuitry or processing circuitry which includes general purpose processors, special purpose processors, integrated circuits, application-specific integrated circuits (ASICs), field-programmable gate arrays (FPGAs), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of an FPGA or ASIC.

1. A liquid discharge system comprising:
a liquid discharge head including:
a nozzle member having a nozzle to discharge a liquid;
a liquid chamber member having a liquid chamber communicating with the nozzle and storing the liquid to be supplied to the nozzle; and
an actuator to deform the liquid chamber to discharge the liquid in the liquid chamber from the nozzle; and
a pressurizer to apply pressure to the liquid in the liquid chamber to maintain the liquid in the liquid chamber at a positive pressure to perform a pressurizing operation; and
wherein the liquid discharge head discharges the liquid, in the liquid chamber, maintained at the positive pressure from the nozzle.

2. The liquid discharge system according to claim 1, further comprising:
a liquid amount detector to detect a liquid amount of the liquid in the liquid chamber; and
circuitry configured to control the pressurizer to perform the pressurizing operation based on the liquid amount in the liquid chamber detected by the liquid amount detector.

3. The liquid discharge system according to claim 1, wherein:
the nozzle member includes the actuator inside the nozzle member, and
the actuator vibrates the nozzle member to discharge the liquid in the liquid chamber from the nozzle.

4. The liquid discharge system according to claim 1, wherein:
the pressurizer applies pressure to the liquid in the liquid chamber with a pressurizing force of 50 kilopascal (kPa) or higher to maintain the liquid in the liquid chamber at the positive pressure.

5. The liquid discharge system according to claim 1, wherein:
the liquid discharge head has the nozzle having a diameter of 100 μm or less.

6. The liquid discharge system according to claim 1, further comprising a heater on an outer surface of the liquid discharge head,
to heat the liquid in the liquid chamber.

7. The liquid discharge system according to claim 6, wherein:
the heater heats the liquid in the liquid chamber to a temperature of 200° C. or higher.

8. The liquid discharge system according to claim 1, wherein:
the liquid discharge head discharges the liquid having a surface tension of 300 mN/m or higher from the nozzle.

9. The liquid discharge system according to claim 1, wherein:
the liquid discharge head discharges the liquid including a liquid or paste metal material containing a metal or an alloy from the nozzle.

10. The liquid discharge system according to claim 1, wherein:
the liquid discharge head discharges the liquid including molten solder from the nozzle.

11. The liquid discharge system according to claim 1, wherein:
the pressurizer supplies an inert gas to the liquid chamber to pressurize the liquid in the liquid chamber.

12. The liquid discharge system according to claim 2, wherein:
the circuitry is further configured to:
apply a voltage to the actuator multiple times in succession to discharge the liquid in the liquid chamber through the nozzle,
while the pressurizer maintains the liquid in the liquid chamber at the positive pressure.

13. A liquid discharge method of discharging a liquid, comprising:
deforming a liquid chamber of a liquid discharge head, the liquid chamber communicating with a nozzle and storing the liquid to be supplied to the nozzle; and
applying pressure to the liquid in the liquid chamber to maintain the liquid in the liquid chamber at a positive pressure to perform a pressurizing operation to discharge the liquid in the liquid chamber from the nozzle; and
wherein the liquid discharge head discharges the liquid, in the liquid chamber, maintained at the positive pressure from the nozzle.

14. The liquid discharge system according to claim 1, wherein:
the pressurizer maintains the liquid in the liquid chamber at the positive pressure,
to maintain the liquid in the nozzle to form a convex meniscus that protrudes outward from a nozzle surface of the nozzle member.
